(19) United States
(12) Patent Application Publication
(10) Pub. No.: US 2026/0143998 A1
(43) Pub. Date: May 21, 2026

(54) FIXING DEVICE AND TOP-OPENING SUBSTRATE CARRIER USING THE SAME

(71) Applicant: Gudeng Precision Industrial Co., LTD., New Taipei City (TW)

(72) Inventors: Ming-Chien Chiu, New Taipei City (TW); Chi-Lin Li, New Taipei City (TW); Chia-Ch Lin, New Taipei City (TW); Yung-Chin Pan, New Taipei City (TW)

(21) Appl. No.: 19/390,911

(22) Filed: Nov. 17, 2025

Related U.S. Application Data
(60) Provisional application No. 63/721,583, filed on Nov. 18, 2024.

(51) Int. Cl. H01L 21/673

(52) U.S. Cl. CPC H10P 72/1914; H10P 72/1921

(57) ABSTRACT

A fixing device and a top-opening substrate carrier using the same include a fixing base and a sliding bar. The top-opening substrate carrier is configured to accommodate multiple substrate trays. The fixing base is fixed to a lateral wall of the top-opening substrate carrier. The sliding bar is slidably assembled with the fixing base so as to be indirectly connected to the top-opening substrate carrier. The sliding bar includes more than one positioning block spaced apart from each other. Each positioning block is configured to press against and secure a corresponding one of the substrate trays. When a door of the top-opening substrate carrier is locked, the sliding bar is pushed by the door to a pressing position so as to press against and secure at least one of the substrate trays.

### RELATED APPLICATIONS

This application claims priority to U.S. Provisional Patent Application No. 63/721,583, by CHIU, et al., titled “FIXING DEVICE AND TOP-OPENING SUBSTRATE CARRIER USING THE SAME,” filed on Nov. 18, 2024, which is hereby incorporated by reference in their entirety.

### BACKGROUND OF THE INVENTION

### Technical Field

The present invention relates to a fixing device and a substrate carrier using the same. More particularly, the present invention relates to a fixing device and a top-opening substrate carrier for use in the field of semiconductor technology.

### Description of Related Art

In the semiconductor industry, various types of substrates are widely used in processes related to the manufacture of semiconductor devices. Whether these substrates are used in the initial, intermediate, or post-fabrication processes, there is a need for transporting or moving the substrates between different work stations. In known applications, the substrates are accommodated in a substrate carrier to prevent collisions and contaminations from the external environment. These substrate carriers provide steady support for multiple substrates at the same time and also facilitate automated substrate loading and unloading operations.

One known type of substrate carrier uses multiple horizontally stacked trays to support and secure the substrates. However, the trays stored therein are easily subject to collisions and vibrations during the movement or transport of the substrate carrier. Even slight movement of the trays may generate particles that contaminate the substrates or may even cause damage to the substrates.

Therefore, there exists a need in the industry for a mechanism that can steadily receive and store the trays in the substrate carrier.

### SUMMARY

In view of the above-mentioned problems, the present invention is to provide a fixing device and a top-opening substrate carrier using the same. When a door and a shell of the top-opening substrate carrier are locked together, an accommodation space is enclosed, and the door pushes the fixing device to press against and secure the substrate trays, thereby securing fixing the substrate trays reliably. The movement of the substrate trays in both horizontal and vertical directions is limited. Problems such as particles generated by the movement of the substrate trays and damage to the substrates can be prevented.

According to one aspect of the invention, a top-opening substrate carrier is provided. The substrate carrier includes a shell and a door. The shell includes a bottom portion and a continuously surrounding lateral wall that together define an accommodating space. The shell has an upper opening opposite to the bottom portion, and the upper opening allows numerous substrate trays to enter and exit the accommodating space. The door is disposed at the upper opening and is configured to lock with the shell to enclose the accommodating space.

According to another aspect of the invention, a fixing device is provided. The fixing device is adapted to be used in a top-opening substrate carrier configured to accommodate several substrate trays. The fixing device includes a fixing base and a sliding bar. The fixing base is fixed to a lateral wall of the top-opening substrate carrier. The sliding bar is slidably assembled with the fixing base so as to be indirectly connected to the top-opening substrate carrier. The sliding bar includes multiple positioning blocks spaced apart from each other, and each of the positioning blocks is configured to press against and secure a corresponding one of the substrate trays. When a door of the top-opening substrate carrier is locked, the sliding bar is pushed by the door to a pressing position so as to press against and secure at least one of the substrate trays.

In one embodiment, each of the positioning blocks has a positioning inclined surface configured to contact a side edge of a corresponding one of the substrate trays, such that when the sliding bar is pushed by the door, a portion of the side edge slides along the positioning inclined surface.

In another embodiment, a rib is provided at a top end of the sliding bar, and the rib is configured to contact a sliding inclined surface of the door and to slide relative thereto.

In yet another embodiment, a sliding pin is provided on a side surface of the sliding bar, and the fixing base has a guiding inclined slot configured to allow the sliding pin to slide therein, thereby guiding a relative movement of the sliding bar with respect to the fixing base.

In a further embodiment, the fixing device further includes an elastic member connected between the fixing base and the sliding bar. When the sliding bar is in the pressing position, the elastic member stores an elastic potential energy, which moves the sliding bar to a releasing position to release at least one of the substrate trays.

In one embodiment, the fixing device further includes a supporting pillar disposed inside the sliding bar to increase a mechanical strength of the sliding bar.

According to yet another aspect of the invention, a top-opening substrate carrier is provided. The top-opening substrate carrier includes a shell, multiple substrate trays, a door, and a fixing device. The shell includes a continuously surrounding lateral wall and a bottom portion that together define an accommodating space. The substrate trays are configured to support multiple semiconductor substrates, and the substrate trays are accommodated in the accommodating space. The door is configured to lock with the shell to enclose the accommodating space. The fixing device includes a fixing base and a sliding bar. The fixing base is fixed to the lateral wall. The sliding bar is slidably assembled with the fixing base, and the sliding bar includes multiple positioning blocks spaced apart from each other. The positioning blocks are configured to press against and secure the substrate trays. When the door is locked with the shell, the sliding bar is pushed by the door to a pressing position so as to press against and secure the substrate trays.

According to the embodiments of the invention, the substrate trays are automatically pressed and secured by the fixing device when the door is locked, thereby simplifying the operation and improving the convenience of use. The substrate trays are secured in both horizontal and vertical directions, providing effective fixation. Further, since the movement of the substrate trays is limited, particle generation is prevented and damage to the substrates is avoided.

### BRIEF DESCRIPTION OF DRAWINGS

The present invention can be more fully understood by reading the following detailed description of the embodiment, with reference made to the accompanying drawings as follows.

FIG. 1 is a three-dimensional view of a top-opening substrate carrier according to one embodiment of the invention.

FIG. 2 is a three-dimensional view of the top-opening substrate carrier of FIG. 1 with the door open.

FIG. 3 is an exploded view of the top-opening substrate carrier of FIG. 1.

FIG. 4 is a three-dimensional view of one substrate tray according to one embodiment of the invention.

FIG. 5a is a three-dimensional view of a fixing device according to one embodiment of the invention.

FIG. 5b is another three-dimensional view of the fixing device of FIG. 5a from a different angle.

FIG. 6 is an exploded view of the fixing device of FIG. 5a.

FIG. 7a is a cross-sectional view of the top-opening substrate carrier when the door is in an open state.

FIG. 7b is a cross-sectional view of the top-opening substrate carrier before the door is locked with the shell.

FIG. 7c is a cross-sectional view of the top-opening substrate carrier when the door is locked with the shell.

### DETAILED DESCRIPTION

In the embodiments of the present invention, a fixing device and a top-opening substrate carrier using the same are provided. When a door and a shell of the substrate carrier are locked with each other, the fixing device presses against and secures the substrate trays, such that the substrate trays are firmly fixed in both horizontal and vertical directions. This effectively prevents various problems caused by the undesired movement of the substrate trays.

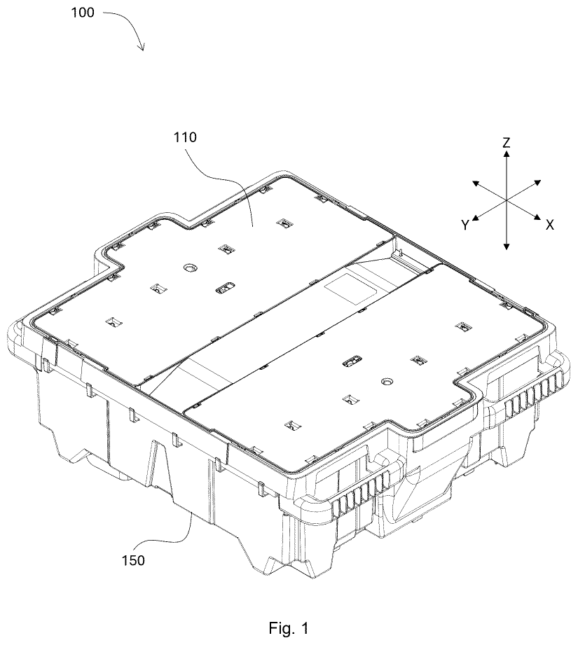

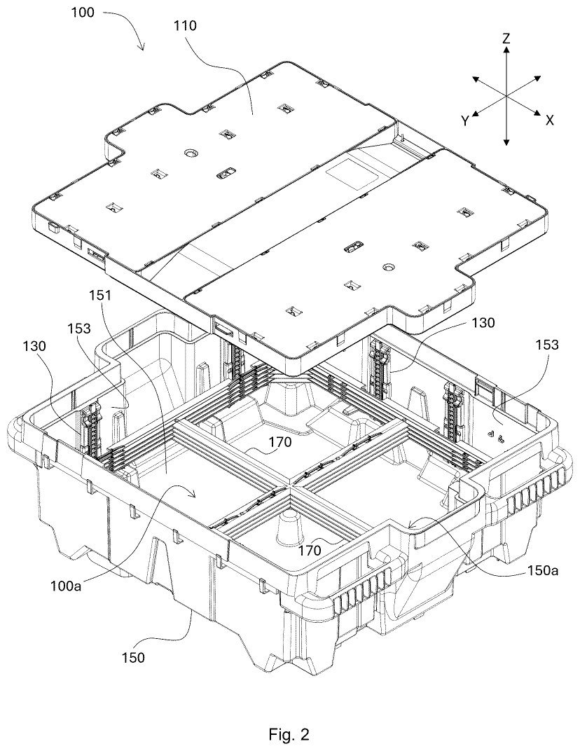

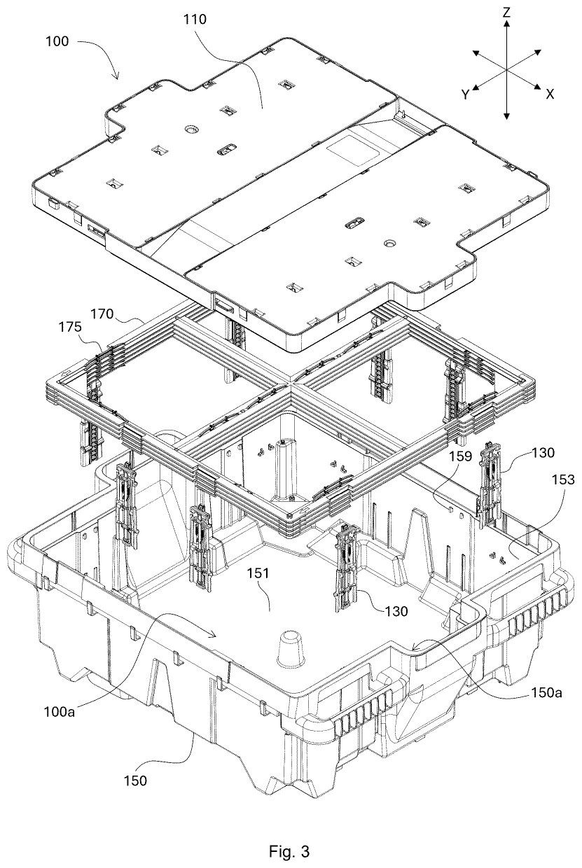

Please refer to FIG. 1 to FIG. 3. FIG. 1 is a three-dimensional view of a top-opening substrate carrier according to one embodiment of the invention. FIG. 2 is a three-dimensional view of the top-opening substrate carrier of FIG. 1 with the door open. FIG. 3 is an exploded view of the top-opening substrate carrier of FIG. 1.

The top-opening substrate carrier 100 according to the present embodiment includes a shell 150 and a door 110. The shell 150 includes a bottom portion 151 and a continuously surrounding lateral wall 153 that together define an accommodating space 100a. The shell 150 has an upper opening 150a opposite to the bottom portion 151, allowing multiple substrate trays 170 to enter and exit the accommodating space 100a. The door 110 is disposed at the upper opening 150a and is configured to engage and lock with the shell 150 to enclose the accommodating space 100a. The shape of the door 110 corresponds to the shape of the upper opening 150a of the shell 150, so that the door 110 can be properly fitted and locked with the shell 150. In addition, the door 110 includes a locking mechanism configured to lock the door 110 to the shell 150 to achieve a desired sealing effect. The manner in which the door 110 engages with the shell 150 and the structural design of the locking mechanism are not limited in the present invention. Any type of locking mechanism that allows a door of a semiconductor container to be engaged and locked with a shell may be adopted in the present invention.

The top-opening substrate carrier 100 of the present embodiment includes multiple substrate trays 170 that are configured to support multiple semiconductor substrates. The shape, type, or thickness of the semiconductor substrates are not limited in the embodiments of the invention. Any substrate usable in semiconductor manufacturing processes that requires a high degree of cleanliness can be used here as the workpiece supported by the substrate trays 170 of the present invention. Applicable examples of substrates include, but are not limited to, circular or square substrates, such as wafers, reticles, glass substrates, and printed circuit boards (PCBs). In a preferred embodiment, each semiconductor substrate is individually disposed on a corresponding one of the substrate trays 170 for positioning and support. Each substrate tray 170 may include multiple elastic supporting members 175 configured to elastically contact the corresponding semiconductor substrate and provide support and fixation in the vertical direction (Z-direction). In one embodiment, two or more substrate trays 170 are accommodated within the accommodating space 100a. When two or more substrate trays 170 are accommodated, they are stacked vertically one above another inside the shell 150.

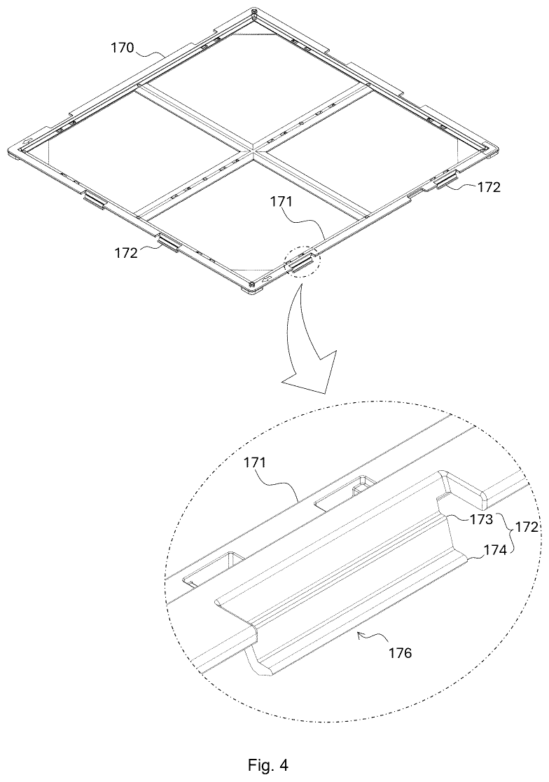

Please refer to FIG. 4, which is a three-dimensional view of one substrate tray according to one embodiment of the invention. Each of the substrate trays 170 includes a main body 171 and a stepped structure 172 connected thereto. The stepped structure 172 extends outwardly from the main body 171 and sequentially includes a first step 173 and a second step 174 having a stepped height difference. The second step 174, which is positioned relatively outward and at a height lower than that of the main body 171, is configured to be pressed and secured by a fixing device. The first step 173, which is positioned relatively inward and at a height higher than that of the second step 174, is configured to press against an adjacent one of the substrate trays 170. The technical features of the stepped structure 172 will be elaborated later in more detail.

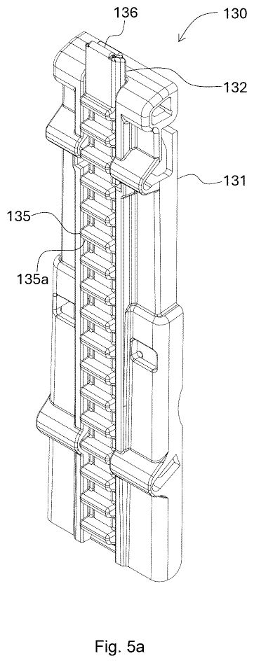

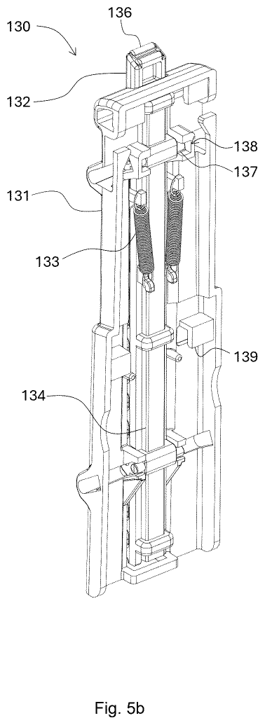

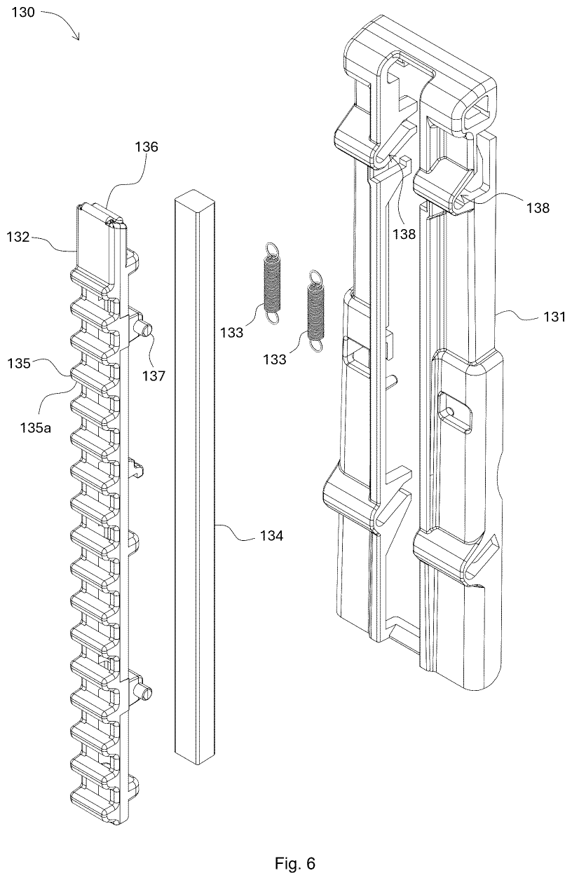

Please refer to FIGS. 5a, 5b, and 6. FIG. 5a is a three-dimensional view of a fixing device according to one embodiment of the invention. FIG. 5b is another three-dimensional view of the fixing device of FIG. 5a from a different angle. FIG. 6 is an exploded view of the fixing device of FIG. 5a. The top-opening substrate carrier 100 of the present embodiment further includes a fixing device 130. It should be noted that although only one fixing device 130 is described herein, it is merely intended for the purpose of clearly elaborating the features of the present invention, and the number of the fixing device 130 is not limited here in the present invention. The top-opening substrate carrier 100 may include a different number of fixing devices 130 as needed. For example, in the embodiment shown in FIGS. 2 and 3, the top-opening substrate carrier 100 includes eight fixing devices 130, which are distributed on the lateral wall 153 of the shell 150, and more specifically, on the inner-facing surface of the lateral wall 153.

The fixing device 130 includes a fixing base 131 and a sliding bar 132. The fixing base 131 is fixed to the lateral wall 153 of the top-opening substrate carrier 100, and the sliding bar 132 is slidably assembled with the fixing base 131 so as to be indirectly connected to the top-opening substrate carrier 100. In the present embodiment, the fixing device 130 is disposed on the inner-facing surface of the lateral wall 153. When the door 110 of the top-opening substrate carrier 100 is locked, the sliding bar 132 is pushed by the door 110 to a pressing position, thereby pressing against and securing the substrate trays 170. In one embodiment, the fixing base 131 is provided with a first locking member 139, which is configured to engage with a second locking member 159 provided on the lateral wall 153 of the shell 150 (as indicated in FIG. 3), thereby fixing the fixing base 131 to the lateral wall 153. The first locking member 139 and the second locking member 159 may have various structural forms and can be designed according to practical needs, in order to fix the fixing base 131 to the lateral wall 153 in either a detachable or non-detachable manner. Alternatively, the fixing base 131 may also be secured to the lateral wall 153 by other known methods such as fusion bonding, welding, or adhesion, and the present invention is not limited thereto.

In one embodiment, the sliding bar 132 includes the following features. First, the sliding bar 132 includes multiple positioning blocks 135 that are spaced apart from each other. Each of the positioning blocks 135 is configured to press against and secure a corresponding one of the substrate trays 170. In addition, at least one rib 136 is provided at a top end of the sliding bar 132. The rib 136 is configured to contact a sliding inclined surface of the door 110 and to slide relative thereto, thereby allowing the door 110 to drive the sliding bar 132 to move relative to the fixing base 131. Furthermore, at least one sliding pin 137 is provided on a side surface of the sliding bar 132, and the fixing base 131 has a guiding inclined slot 138, which allows the sliding pin 137 to slide therein, thereby guiding a relative movement of the sliding bar 132 with respect to the fixing base 131.

The fixing device 130 further includes an elastic member 133, which is connected between the fixing base 131 and the sliding bar 132. When the sliding bar 132 is in the pressing position, the elastic member 133 stores an elastic potential energy, which moves the sliding bar 132 to a releasing position to release at least one of the substrate trays 170. In the present embodiment, the elastic member 133 is exemplified by a pair of tension springs. However, the elastic member 133 may alternatively be any other element that stores potential energy, and its form and material are not limited here in the present invention.

The fixing device 130 of the present embodiment further includes a supporting pillar 134, which is disposed inside the sliding bar 132 to increase a mechanical strength of the sliding bar 132. This prevents the sliding bar 132 from bending, twisting, or other undesired movements during sliding or when pressing and securing the substrate trays 170. Therefore, a more effective fixation of the substrate trays 170 is assured. In one embodiment, the supporting pillar 134 may, for example, be a carbon rod. However, the supporting pillar 134 may alternatively be any other element that provides mechanical support, and its form and material are not limited here in the present invention.

The detailed description now elaborates the movement of the sliding bar 132 relative to the fixing base 131, and describes the technical features associated with the pressing position and the releasing position.

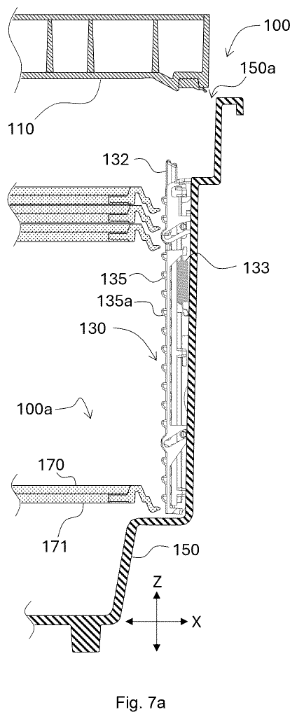

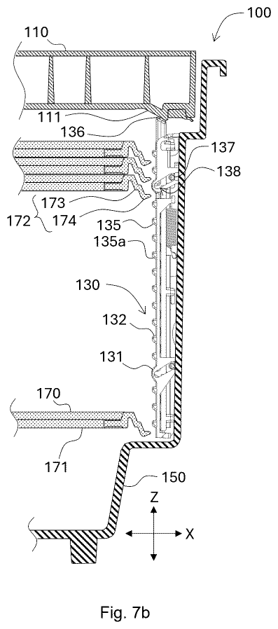

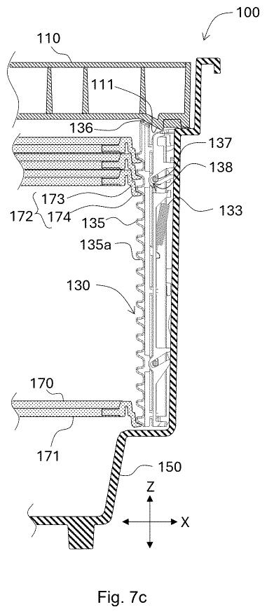

Please refer to FIGS. 7a to 7c. FIG. 7a is a cross-sectional view of the top-opening substrate carrier when the door is in an open state. FIG. 7b is a cross-sectional view of the top-opening substrate carrier before the door is locked with the shell. FIG. 7c is a cross-sectional view of the top-opening substrate carrier when the door is locked with the shell. As shown in FIG. 7a, when the door 110 is open, the door 110 is not in contact with the sliding bar 132 of the fixing device 130. At this time, the sliding bar 132 is maintained in the releasing position by the force of the elastic member 133. The positioning blocks 135 are not in contact with the substrate trays 170, and therefore the substrate trays 170 are not secured by the sliding bar 132. In this state, the substrate trays 170 can be sequentially removed from the accommodating space 100a through the upper opening 150a, or sequentially stacked into the shell 150.

When the door 110 is to be locked with the shell 150, a door closing process is initiated, during which the door 110 moves downward until its sliding inclined surface 111 contacts the sliding bar 132, as shown in FIG. 7b.

When the door 110 continues to move downward from the state shown in FIG. 7b, the door 110 drives the sliding bar 132 via the sliding inclined surface 111, causing the sliding bar 132 to begin moving relative to the fixing base 131 and away from the releasing position. In the present embodiment, a pair of the ribs 136 is provided at the top end of the sliding bar 132. The two ribs 136 are strip-shaped, arranged in parallel, and configured to enhance the stability of the sliding bar 132 when interacting with the sliding inclined surface 111. However, the pair of the ribs 136 provided here is for example only. In an alternative embodiment, the rib 136 may include one or more protrusions at the top end of the sliding bar 132, each having the same height. Any other contact structure on a sliding component may also be applied in the embodiments of the present invention, and its form and material are not limited here in the present invention. Furthermore, since the sliding bar 132 moves with respect to the fixing base 131 via the sliding pin 137, when the sliding bar 132 is driven by the door 110, the sliding pin 137 moves along the guiding inclined slot 138. In the present embodiment, for example, the sliding pin 137 (together with the sliding bar 132) moves toward the lower-left direction in view of FIG. 7b.

During the movement of the sliding bar 132, the positioning blocks 135 begin to contact the stepped structures 172 of the substrate trays 170. As the sliding bar 132 continues to be driven by the door 110 along the guiding inclined slot 138, the positioning blocks 135 press against the second steps 174 of the stepped structures 172, respectively, causing the stepped structures 172 to elastically deform. In the present embodiment, each stepped structure 172 rotates in a clockwise direction relative to the main body 171 of the substrate tray 170, as shown in the transition from FIG. 7b to FIG. 7c.

Further, each of the positioning blocks 135 of the sliding bar 132 has a positioning inclined surface 135a, which is configured to contact a side edge 176 of a corresponding one of the substrate trays 170 (the side edge 176 is shown in FIG. 4). The side edge 176 includes the stepped structure 172. During operation, when the sliding bar 132 is pushed by the door 110, a portion of the side edge 176 slides along the positioning inclined surface 135a. In the present embodiment, it is the second step 174 of the stepped structure 172 that moves along the positioning inclined surface 135a until the sliding bar 132 is pushed to the pressing position, thereby causing the stepped structure 172 to deform.

As shown in FIG. 7c, when the door 110 is fully closed and is locked with the shell 150, the sliding bar 132 is pushed by the sliding inclined surface 111 to the pressing position. At this point, each positioning block 135 presses against and secures the second step 174 via the positioning inclined surface 135a, thereby securing the substrate tray 170 via the second step 174. In addition, the first step 173 of the stepped structure 172 presses against the first step 173 of an adjacent one of the substrate trays 170. The substrate trays 170 are then firmly fixed in both the Z-axis direction and the X-axis direction, effectively limiting their movement in both the horizontal and vertical directions. In this manner, the substrate trays 170 are automatically pressed and secured by the fixing device 130 when the door 110 is locked with the shell 150, which simplifies the operation, thereby improving the convenience of use.

As also shown in FIG. 7c, the elastic member 133 (for example, a tension spring) is in a stretched state, storing elastic potential energy for moving the sliding bar 132. Therefore, when the door 110 is unlocked and opened, the elastic member 133 drives the sliding bar 132 to move along the guiding inclined slot 138 back to the releasing position, releasing the substrate trays 170. The stepped structures 172 of the substrate trays 170 also elastically return to their natural state, as shown in FIG. 7a.

The fixing device and the top-opening substrate carrier using the same according to the embodiments of the invention include the fixing base and the sliding bar. The fixing base is fixed to the lateral wall of the top-opening substrate carrier, and the sliding bar is slidably assembled with the fixing base, thereby being indirectly connected to the top-opening substrate carrier. When the door is locked with the shell, the sliding bar is pushed by the door to the pressing position so as to press against and secure the substrate trays. In this manner, the substrate trays are automatically pressed and secured by the fixing device when the door is locked, which simplifies the operation, thereby improving the convenience of use. Furthermore, the substrate trays are fixed in both the horizontal and vertical directions, providing effective fixation. Since the movement of the substrate trays is limited, particle generation and potential damage to the semiconductor substrates are prevented, thereby further avoiding contamination of the semiconductor substrates.

Although the present invention has been disclosed with a number of embodiments as above, they are not intended to limit the present invention. Any person skilled in the art can make various modifications and refinements without departing from the spirit and scope of the present invention. Therefore, the protection scope of the present invention shall be defined by the scope of the appended claims.

What is claimed is:

1. A top-opening substrate carrier, comprising:
a shell comprising a bottom portion and a continuously surrounding lateral wall that together define an accommodating space, the shell having an upper opening opposite to the bottom portion, the upper opening allowing a plurality of substrate trays to enter and exit the accommodating space; and
a door disposed at the upper opening and configured to lock with the shell to enclose the accommodating space.

2. A fixing device adapted to be used in a top-opening substrate carrier configured to accommodate a plurality of substrate trays, the fixing device comprising:
a fixing base fixed to a lateral wall of the top-opening substrate carrier; and
a sliding bar slidably assembled with the fixing base so as to be indirectly connected to the top-opening substrate carrier, the sliding bar comprising a plurality of positioning blocks spaced apart from each other, each of the positioning blocks being configured to press against and secure a corresponding one of the substrate trays;
wherein, when a door of the top-opening substrate carrier is locked, the sliding bar is pushed by the door to a pressing position so as to press against and secure at least one of the substrate trays.

3. The fixing device according to claim 2, wherein each of the positioning blocks has a positioning inclined surface configured to contact a side edge of a corresponding one of the substrate trays, such that when the sliding bar is pushed by the door, a portion of the side edge slides along the positioning inclined surface.

4. The fixing device according to claim 2, wherein a rib is provided at a top end of the sliding bar, the rib being configured to contact a sliding inclined surface of the door and to slide relative thereto.

5. The fixing device according to claim 2, wherein a sliding pin is provided on a side surface of the sliding bar, and the fixing base has a guiding inclined slot configured to allow the sliding pin to slide therein, thereby guiding a relative movement of the sliding bar with respect to the fixing base.

6. The fixing device according to claim 2, further comprising an elastic member connected between the fixing base and the sliding bar; when the sliding bar is in the pressing position, the elastic member stores an elastic potential energy, which moves the sliding bar to a releasing position to release at least one of the substrate trays.

7. The fixing device according to claim 2, further comprising a supporting pillar disposed inside the sliding bar to increase a mechanical strength of the sliding bar.

8. A top-opening substrate carrier, comprising:
a shell, comprising a continuously surrounding lateral wall and a bottom portion that together define an accommodating space;
a plurality of substrate trays, configured to support a plurality of semiconductor substrates, the substrate trays being accommodated in the accommodating space;
a door, configured to lock with the shell to enclose the accommodating space; and
a fixing device, comprising:
a fixing base, fixed to the lateral wall; and
a sliding bar, slidably assembled with the fixing base, the sliding bar comprising a plurality of positioning blocks spaced apart from each other, the positioning blocks being configured to press against and secure the substrate trays;
wherein, when the door is locked with the shell, the sliding bar is pushed by the door to a pressing position so as to press against and secure the substrate trays.

9. The top-opening substrate carrier according to claim 8, wherein the fixing device further comprises an elastic member connected between the fixing base and the sliding bar; when the sliding bar is in the pressing position, the elastic member stores an elastic potential energy, which moves the sliding bar to a releasing position to release the substrate trays.

10. The top-opening substrate carrier according to claim 8, wherein each of the positioning blocks has a positioning inclined surface configured to contact a side edge of corresponding one of the substrate trays, such that when the sliding bar is pushed by the door, a portion of the side edge slides along the positioning inclined surface.

11. The top-opening substrate carrier according to claim 10, wherein each of the substrate trays comprises a main body and the side edge, and the side edge comprises a stepped structure extending outwardly from the main body and sequentially comprising a first step and a second step, wherein the first step is configured to press against an adjacent one of the substrate trays, and the second step is configured to be pressed and secured by a corresponding one of the positioning blocks.
